(19) United States
(12) Patent Application Publication
(10) Pub. No.: US 2025/0040453 A1
(43) Pub. Date: Jan. 30, 2025

(54) SUPERCONDUCTING RESONANT CIRCUIT AND MEASUREMENT METHOD

(71) Applicant: NEC Corporation, Tokyo (JP)

(72) Inventor: Shun YANAI, Tokyo (JP)

(73) Assignee: NEC Corporation, Tokyo (JP)

(21) Appl. No.: 18/761,451

(22) Filed: Jul. 2, 2024

(30) Foreign Application Priority Data
Jul. 26, 2023 (JP) 2023-121716

(51) Int. Cl. H10N 69/00; H01P 3/00; H01P 7/08; H02N 2/02

(52) U.S. Cl. CPC H10N 69/00; H01P 3/003; H01P 7/088; H02N 2/026

(57) ABSTRACT

A superconducting resonant circuit includes a first superconducting circuit chip including a readout waveguide, a lumped constant inductor, and a first lumped constant capacitor electrode, a second superconducting circuit chip including a second lumped constant capacitor electrode facing the first lumped constant capacitor electrode, and an actuator configured to change an inter-electrode distance between the first lumped constant capacitor electrode and the second lumped constant capacitor electrode.

### CROSS-REFERENCE TO RELATED APPLICATION

Priority is claimed on Japanese Patent Application No. 2023-121716, filed Jul. 26, 2023, the content of which is incorporated herein by reference.

### BACKGROUND ART

The present disclosure relates to a superconducting resonant circuit and a measurement method.

It is known that superconducting resonant circuits are used in quantum devices.

For example, W. Woods, G. Calusine, A. Melville, A. Sevi, E. Golden, D. K. Kim, D. Rosenberg, J. L. Yoder, and W. D. Oliver Phys. Rev. Applied 12, 014012, Published 8 Jul. 2019 (hereinafter referred to as Non-Patent Document 1) discloses a coplanar superconducting resonant circuit.

### SUMMARY

In the superconducting resonant circuit disclosed in Non-Patent Document 1, the loss amount of each insulation part including the dielectric loss between a superconducting metal and air is analyzed.

However, in the analysis method disclosed in Non-Patent Document 1, for example, it may be necessary to make many prototypes of superconducting resonant circuits, and analysis of a dielectric loss may take time.

An example object of the present disclosure is to provide a superconducting resonant circuit for solving the aforementioned problems.

A superconducting resonant circuit according to one example aspect of the present disclosure includes a first superconducting circuit chip including a readout waveguide, a lumped constant inductor, and a first lumped constant capacitor electrode, a second superconducting circuit chip including a second lumped constant capacitor electrode facing the first lumped constant capacitor electrode, and an actuator configured to change an inter-electrode distance between the first lumped constant capacitor electrode and the second lumped constant capacitor electrode.

A measurement method according to one example aspect of the present disclosure is a measurement method for a superconducting resonant circuit including a first superconducting circuit chip including a readout waveguide, a lumped constant inductor, and a first lumped constant capacitor electrode, and a second superconducting circuit chip including a second lumped constant capacitor electrode facing the first lumped constant capacitor electrode, the measurement method including changing an inter-electrode distance between the first lumped constant capacitor electrode and the second lumped constant capacitor electrode, and measuring high frequency response characteristics of the superconducting resonant circuit.

A superconducting resonant circuit according to one example aspect of the present disclosure includes a first superconducting circuit chip including a readout waveguide and a first lumped constant capacitor electrode, a second superconducting circuit chip including a lumped constant inductor and a second lumped constant capacitor electrode facing the first lumped constant capacitor electrode, and an actuator configured to change an inter-electrode distance between the first lumped constant capacitor electrode and the second lumped constant capacitor electrode.

A measurement method according to one example aspect of the present disclosure is a measurement method for a superconducting resonant circuit including a first superconducting circuit chip including a readout waveguide and a first lumped constant capacitor electrode, and a second superconducting circuit chip including a lumped constant inductor and a second lumped constant capacitor electrode facing the first lumped constant capacitor electrode, the measurement method including changing an inter-electrode distance between the first lumped constant capacitor electrode and the second lumped constant capacitor electrode, and measuring high frequency response characteristics of the superconducting resonant circuit.

According to the above aspect, analysis of a dielectric loss does not take much time.

### BRIEF DESCRIPTION OF THE DRAWINGS

FIG. 1 is a partial sectional front view illustrating an example of a superconducting resonant circuit according to some example embodiments of the present disclosure.

FIG. 2 is a sectional view taken along line II-II in FIG. 1.

FIG. 3 is a sectional view taken along line III-III in FIG. 2.

FIG. 4 is a sectional view taken along line IV-IV in FIG. 1.

FIG. 5 is a sectional view taken along line V-V in FIG. 4.

FIG. 6 is a diagram illustrating an example of an operation of a superconducting resonant circuit according to the present disclosure.

FIG. 7 is a flowchart illustrating an example of a measurement method according to the present disclosure.

FIG. 8 is an equivalent circuit diagram illustrating an example of the superconducting resonant circuit according to the present disclosure.

FIG. 9 is a partially sectional front view illustrating an example of a superconducting resonant circuit according to the present disclosure.

FIG. 10 is a sectional view taken along line X-X in FIG. 9.

FIG. 11 is a sectional view taken along line XI-XI in FIG. 10.

FIG. 12 is a sectional view taken along line XII-XII in FIG. 9.

FIG. 13 is a sectional view taken along line XIII-XIII in FIG. 12.

FIG. 14 is an equivalent circuit diagram illustrating an example of the superconducting resonant circuit according to the present disclosure.

FIG. 15 is a partially sectional front view illustrating an example of a superconducting resonant circuit according to the present disclosure.

FIG. 16 is a sectional view taken along line XVI-XVI in FIG. 15.

FIG. 17 is a sectional view taken along line XVII-XVII in FIG. 15.

FIG. 18 is an equivalent circuit diagram illustrating an example of the superconducting resonant circuit according to the present disclosure.

FIG. 19 is a partially sectional front view illustrating an example of a superconducting resonant circuit according to the present disclosure.

FIG. 20 is a sectional view taken along line XX-XX in FIG. 19.

FIG. 21 is a sectional view taken along line XXI-XXI in FIG. 19.

FIG. 22 is an equivalent circuit diagram illustrating an example of the superconducting resonant circuit according to the present disclosure.

FIG. 23 is a partially sectional front view illustrating an example of a superconducting resonant circuit according to the present disclosure.

FIG. 24 is a sectional view taken along line XXIV-XXIV in FIG. 23.

FIG. 25 is a sectional view taken along line XXV-XXV in FIG. 23.

FIG. 26 is an equivalent circuit diagram illustrating an example of the superconducting resonant circuit according to the present disclosure.

FIG. 27 is an enlarged view of part XXVII in FIG. 26.

FIG. 28 is a partially sectional front view illustrating an example of a superconducting resonant circuit according to the present disclosure.

FIG. 29 is a partially sectional front view illustrating an example of a superconducting resonant circuit according to the present disclosure.

FIG. 30 is a flowchart illustrating an example of a measurement method according to the present disclosure.

### EXAMPLE EMBODIMENT

Hereinafter, various example embodiments according to the present disclosure will be described using the drawings.

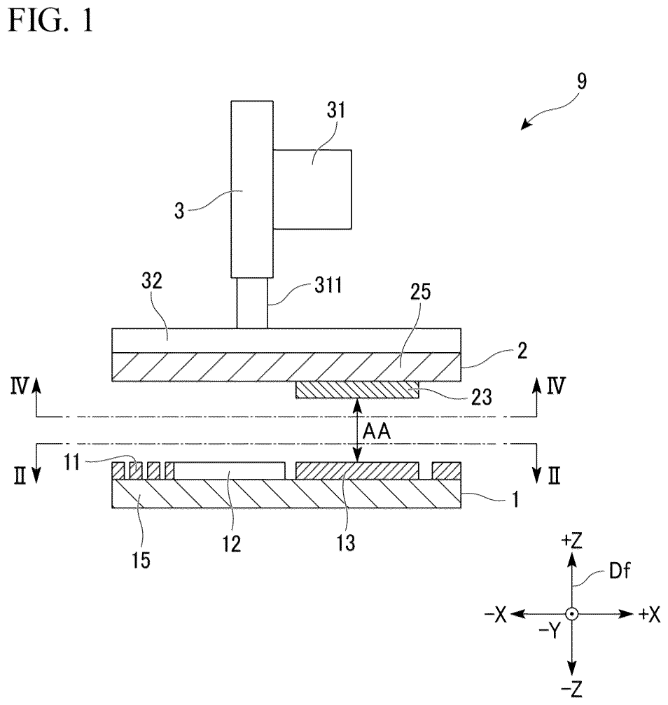

Hereinafter, some example embodiments according to the present disclosure will be described using FIG. 1 to FIG. 8.

### (Configuration of Superconducting Resonant Circuit)

As shown in FIG. 1, a superconducting resonant circuit 9 includes a first superconducting circuit chip 1, a second superconducting circuit chip 2, and an operating mechanism 3.

The first superconducting circuit chip 1 and the second superconducting circuit chip 2 face each other in a facing direction Df.

The superconducting resonant circuit 9 can move the first superconducting circuit chip 1 and the second superconducting circuit chip 2 closer to or farther apart from each other using the operating mechanism 3.

For example, the superconducting resonant circuit 9 is an LC resonant circuit.

Note that, hereinafter, one of the facing directions Df is also referred to as a +Z direction and the other is referred to as a-Z direction.

Further, one of first directions in the plane perpendicular to the facing directions Df is referred to as a +X direction, and the other is referred to as a −X direction.

Further, one of second directions in the plane perpendicular to the facing directions Df is referred to as a +Y direction, and the other is referred to as a −Y direction.

For example, the ±Z direction, the ±X direction, and the ±Y direction may be directions orthogonal to each other.

For example, the ±Z direction may be a vertical direction, and the XY plane may be a horizontal plane.

### (Configuration of First Superconducting Circuit Chip)

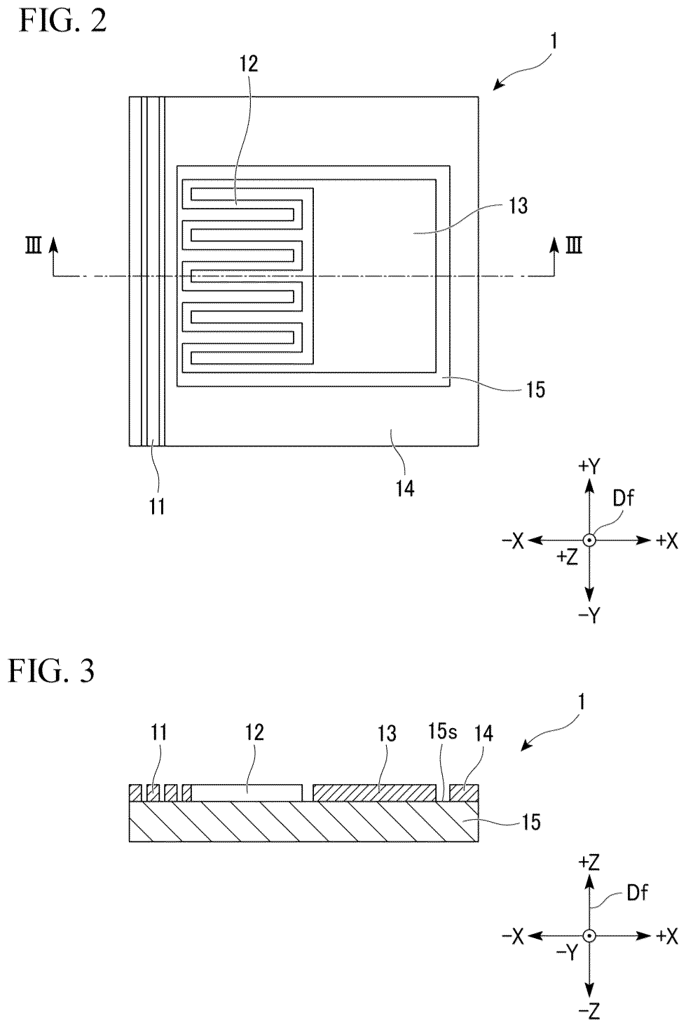

As shown in FIG. 2 and FIG. 3, the first superconducting circuit chip 1 includes a readout waveguide 11, a lumped constant inductor 12, a first lumped constant capacitor electrode 13, a ground pattern 14, and a first substrate 15.

The first substrate 15 has a first surface 15s on the +Z direction side as one of a pair of substrate surfaces along the XY plane.

For example, the first surface 15s is a flat surface.

For example, the first substrate 15 may be made of an insulator.

For example, the first substrate 15 may be a silicon substrate or a sapphire substrate.

For example, each of the readout waveguide 11, the lumped constant inductor 12, the first lumped constant capacitor electrode 13, and the ground pattern 14 may be formed of a thin film pattern along the XY plane.

Each of the readout waveguide 11, the lumped constant inductor 12, the first lumped constant capacitor electrode 13, and the ground pattern 14 is provided on the first surface 15s of the first substrate 15.

For example, each of the readout waveguide 11, the lumped constant inductor 12, the first lumped constant capacitor electrode 13, and the ground pattern 14 may be made of a superconducting metal.

Such a superconducting metal may be a substance that functions as a superconductor at extremely low temperatures.

Such a superconducting metal may be aluminum (Al), niobium (Nb), titanium nitride (TiN), or tantalum (Ta).

The readout waveguide 11 and the lumped constant inductor 12 are coupled to each other with respect to microwaves.

For example, the readout waveguide 11 is a coplanar waveguide.

### (Configuration of Second Superconducting Circuit Chip)

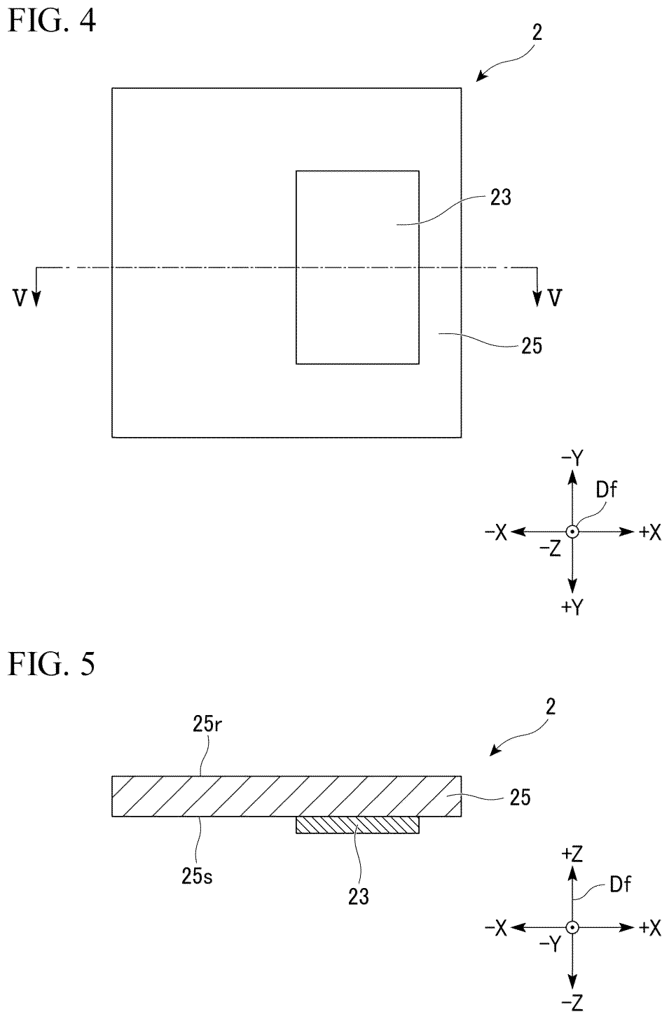

As shown in FIG. 4 and FIG. 5, the second superconducting circuit chip 2 includes a second lumped constant capacitor electrode 23 and a second substrate 25.

The first lumped constant capacitor electrode 13 and the second lumped constant capacitor electrode 23 face each other in the facing direction Df.

The second substrate 25 has a second surface 25s on the −Z direction side and a third surface 25r on the +Z direction side as a pair of substrate surfaces along the XY plane.

The second surface 25s faces the first surface 15s.

For example, each of the second surface 25s and the third surface 25r is a flat surface.

For example, the second substrate 25 may be made of an insulator.

For example, the second substrate 25 may be a silicon substrate or a sapphire substrate.

The second lumped constant capacitor electrode 23 may be formed of a thin film pattern along the XY plane.

The second lumped constant capacitor electrode 23 is provided on the second surface 25s.

For example, the second lumped constant capacitor electrode 23 may be made of superconducting metal.

Such a superconducting metal may be a substance that functions as a superconductor at extremely low temperatures.

Such a superconducting metal may be aluminum (Al), niobium (Nb), titanium nitride (TiN), or tantalum (Ta).

### (Configuration of Operating Mechanism 3)

The operating mechanism 3 is capable of changing the inter-electrode distance AA between the first lumped constant capacitor electrode 13 and the second lumped constant capacitor electrode 23.

For example, the operating mechanism 3 changes the inter-electrode distance AA by moving the second superconducting circuit chip 2 with respect to the first superconducting circuit chip 1 in the facing direction Df.

As shown in FIG. 1, the operating mechanism 3 includes an actuator 31 and a fixing jig 32.

The actuator 31 includes a rod 311.

The rod 311 extends in the facing direction Df.

For example, the actuator 31 may be a piezo actuator.

The fixing jig 32 is fixed to the third surface 25r of the second substrate 25.

For example, the fixing jig 32 may be a copper plate attached to the third surface 25r.

The fixing jig 32 is fixed to the tip of the rod 311.

Accordingly, the actuator 31 can move the second superconducting circuit chip 2 in the facing direction Df via the fixing jig 32 by driving the rod 311 back and forth in the facing direction Df. Therefore, the actuator 31 can move the second superconducting circuit chip 2 closer to or farther apart from the first superconducting circuit chip 1.

### (Operation of Superconducting Resonant Circuit)

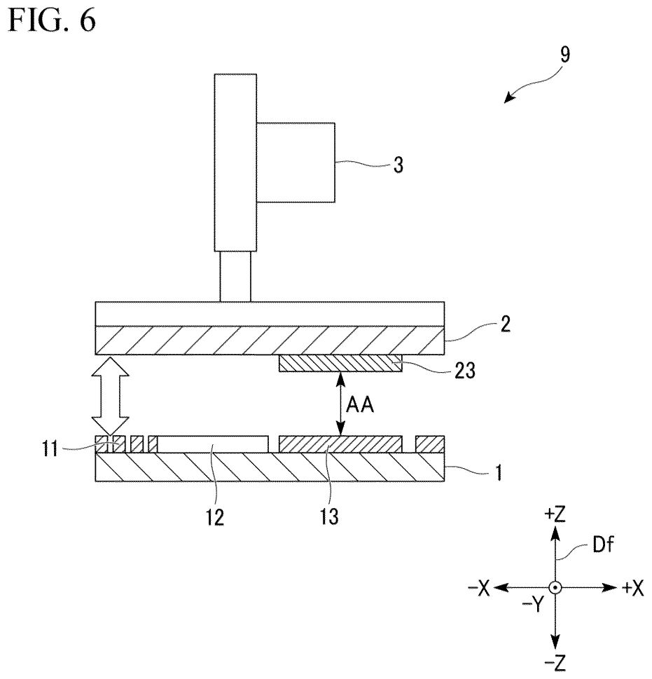

As shown in FIG. 6, the superconducting resonant circuit 9 can move the first superconducting circuit chip 1 and the second superconducting circuit chip 2 closer to or farther apart from each other using the operating mechanism 3. Accordingly, the inter-electrode distance AA between the first lumped constant capacitor electrode 13 and the second lumped constant capacitor electrode 23 can be changed.

For example, by bringing the first superconducting circuit chip 1 and the second superconducting circuit chip 2 closer to each other, a capacitor is formed between the first lumped constant capacitor electrode 13 and the second lumped constant capacitor electrode 23, and creates a resonance mode together with an inductor formed in the first superconducting circuit chip 1. A loss derived from TLS, which will be described later, is defined as the sum of loss tangents (tan 8) of each loss source multiplied by a value representing a weight and a participation ratio.

### (Measurement Method)

Hereinafter, a measurement method of the present example embodiment will be described.

The measurement method of the present example embodiment is a method for measuring high frequency response characteristics of the superconducting resonant circuit 9.

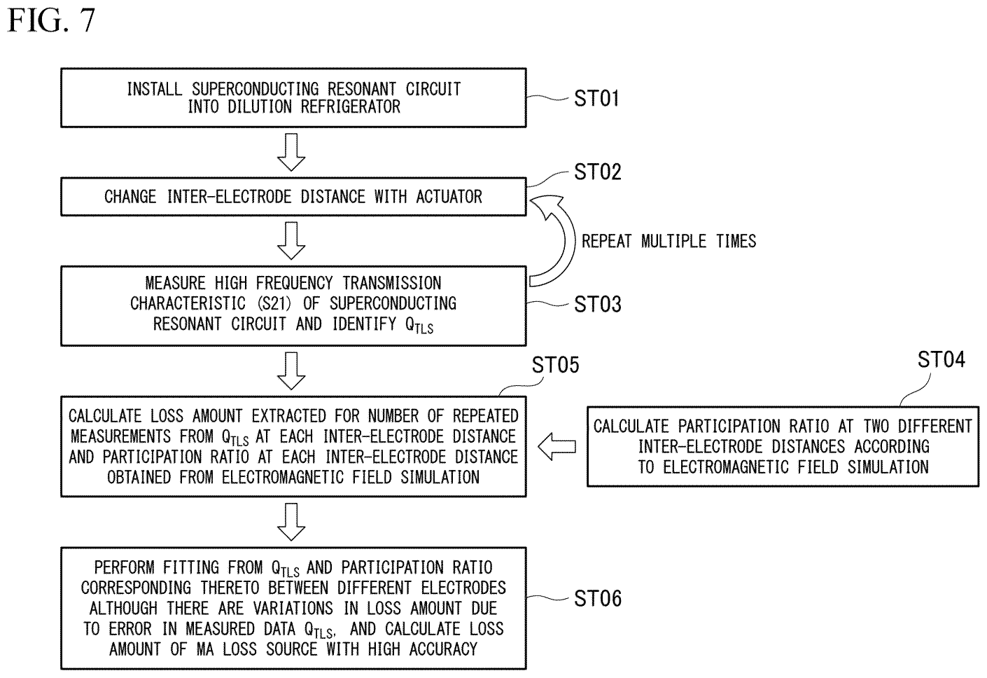

As shown in FIG. 7, a measurer first installs the superconducting resonant circuit 9 into a dilution refrigerator (ST01).

Subsequently to the implementation of ST01, the measurer drives the actuator 31 to change the inter-electrode distance AA between the first lumped constant capacitor electrode 13 and the second lumped constant capacitor electrode 23 (ST02). At that time, the measurer may measure the high frequency transmission characteristics of the superconducting resonant circuit 9 before changing the inter-electrode distance AA as an initial value.

Subsequently to the implementation of ST02, the measurer measures the high frequency transmission characteristics of the superconducting resonant circuit 9 at the changed inter-electrode distance AA (ST03). In addition, the measurer identifies Q_{TLS}, which will be described later, on the basis of the measured high frequency transmission characteristics.

After the implementation of ST03, the measurer returns to ST02 and repeats ST02 and ST03 many times.

On the other hand, the measurer calculates a participation ratio, which will be described later, at different inter-electrode distances AA by electromagnetic field simulations (ST04).

Subsequently to the repeated implementation of ST02 and ST03 and the implementation of ST04, the measurer calculates a loss amount extracted for the number of repeated measurements from the Q_{TLS} identified at each inter-electrode distance AA and participation ratio (ST05).

Subsequently to the implementation of ST05, the measurer performs fitting from the Q_{TLS} and participation ratio at each inter-electrode distance AA (ST06).

Since there are variations in a plurality of loss amounts extracted in ST04 due to a measurement error of Q_{TLS}, it is possible to calculate a loss amount of an MA loss source which will be described later with high accuracy by performing such fitting.

### (Operation and Effect)

According to the superconducting resonant circuit 9 of the present example embodiment, since the inter-electrode distance AA can be changed, the capacitance of the capacitor constituted by the first lumped constant capacitor electrode 13 and the second lumped constant capacitor electrode 23 can be changed.

Accordingly, the high frequency response characteristics of the superconducting resonant circuit 9 can be measured by changing the capacitance value.

Therefore, according to the superconducting resonant circuit 9, it takes less time to analyze a dielectric loss.

According to an example of the superconducting resonant circuit 9 of the present embodiment, the measurer can extract a loss amount with high accuracy as described below.

A large proportion of coherence (energy relaxation time, internal Q value) of a superconducting quantum circuit is contributed by a dielectric loss called a two level system (TLS). On the other hand, a method called surface loss extraction (SLE) makes it possible to quantitatively extract a loss amount in a superconducting resonant circuit.

A resonator-derived TLS loss (Fδ_{TLS}) can be obtained from the power dependence of the internal Q value of coplanar resonators having different cross sections.

As a comparative example, there is a method of reproducing a shape of a measurement resonator using computer aided design (CAD) from a cross-sectional scanning electron microscope (SEM) of the measurement resonator and embedding loss sources that may be present on a device into a CAD design.

Here, the loss sources that may be present may be conceived to be present at a total of four portions between a superconducting metal and a substrate (MS), between the substrate and air (SA), between the superconducting metal and air (MA), and within a bulk substrate (Sub).

Therefore, according to the method of this comparative example, it is possible to extract the loss amount of each insulation part from the proportion of energy stored in each insulation part obtained from electromagnetic field simulations and the TLS-derived internal Q value obtained from measurement.

However, in order to extract the loss amount of a superconducting resonator prototyped using the analysis method of this comparative example, there are problems that it is necessary to measure a large number of resonators, and it takes a long time to prototype a device. The main reason is that, in this loss amount extraction experiment, there are variations in the Q value obtained from the experiment. Another reason is that a loss amount is calculated from a participation ratio that indicates a weight representing how much electrostatic energy is stored in the insulation part, which is obtained from electromagnetic field simulations, but calculation of the participation ratio with high accuracy is a major challenge due to the structure of the device. Uncertainty in the Q value and the participation ratio greatly affects the uncertainty in a loss amount to be obtained.

On the other hand, according to the superconducting resonant circuit 9 of the present embodiment, the loss amount only between the superconducting metal and air, which is considered to have the largest contribution among the four loss amounts, can be easily extracted with higher accuracy. In this method, the structure of the resonator is simplified, and thus improvement of the accuracy of electromagnetic field simulation is expected. Further, by using the actuator 31, the geometry of a single device can be changed, and a loss amount can be extracted with high accuracy.

Therefore, it is possible to extract a loss amount with high accuracy.

In addition, since it is possible to extract the loss amount between the superconducting metal and air with higher accuracy, the measurer can also accurately calculate the participation ratio between the superconducting metal and air.

According to an example of the superconducting resonant circuit 9 of the present embodiment, the measurer can easily measure high-frequency response characteristics over different inter-electrode distances AA, as described below.

In extracting a loss amount using SLE, it is necessary to measure a large number of resonators each designed to emphasize insulation parts with different cross sections. The reason why a large number of resonator measurements is required is that there are variations in the internal Q value between devices in each resonator.

As disclosed in Non-Patent Document 1, the reciprocal of the TLS-derived internal Q value is determined by the sum of products of participation ratio Pi and loss amount xᵢ determined from the device geometry in insulation parts (MS, SA, MA, and Sub). Specifically, the reciprocal of the internal Q value is represented by Formula (1) below.

$$\frac{1}{{Q}_{TLS}} = {\sum }_{i} {P}_{i} {x}_{i} \qquad Formula ( 1 )$$

Here, i represents each insulating part (MS, SA, MA, and Sub). The participation ratio is defined as the ratio (Uᵢ/Uₜₒₜ) of the electrostatic energy Uᵢ stored in each insulating part to the electrostatic energy Uₜₒₜ stored in the entire device space. A 4×4 matrix can be created from the partition ratios of four devices created such that respective insulation parts with different cross sections are emphasized. In addition, if the devices are prototyped such that each cross section is well emphasized, then this participation ratio matrix will approach linear independence more closely. 1/Q_{TLS} obtained from the experiment on the left side of Formula (1) can also construct a [4×1] matrix by measuring four resonators with different geometries. By solving the inverse problem of the above simultaneous equations, it is possible to extract the loss amount in each insulation part.

However, Q_{TLS}, which is the Q value derived from TLS on the left side of Formula (1), has variations between devices, and thus it is necessary to measure a large number of resonators with four different cross sections in order to reflect a more accurate Q value.

On the other hand, according to the superconducting resonant circuit 9 of the present embodiment, the inter-electrode distance AA can be changed, and thus the measurer can easily measure the high-frequency response characteristics over different inter-electrode distances AA.

In addition, by reducing increments of the inter-electrode distance AA for measurement, the measurer can extract a loss amount at the superconducting metal-air (vacuum) interface with high accuracy.

According to an example of the superconducting resonant circuit 9 of the present embodiment, the measurer can easily extract the loss amount in the insulation part between the superconducting metal and air (MA) as described below.

For example, in the case of being compared with a two-dimensional coplanar resonator, the electrostatic energy stored at the superconducting metal-substrate (MS) interface, at the substrate-air (SA) interface, and in the substrate (Sub) can be ignored, and the electrostatic energy of a resonant circuit using a parallel plate capacitor such as the superconducting resonant circuit 9 of the present embodiment is mainly stored at the interface between air and superconducting metal/air (Metal/Air). If an LC resonant circuit is composed of two chips like the superconducting resonant circuit 9 of the present embodiment, the electric field density at the MA interface can be changed by changing the distance between the chips, and thus it is possible to probe changes in the loss amount at the MA interface using a single device without fabricating elements of a plurality of levels.

Therefore, according to the superconducting resonant circuit 9, the measurer can easily extract the loss amount in the insulation part between the superconducting metal and air (MA).

According to an example of the superconducting resonant circuit 9 of the present embodiment, the measurer can calculate the internal Q value of the superconducting resonant circuit 9 as follows.

In the superconducting resonant circuit 9 of the present embodiment, since the inter-electrode distance AA can be changed by the actuator 31, the measurer can change the capacitance between the first lumped constant capacitor electrode 13 and the second lumped constant capacitor electrode 23.

As a result, the electric field density at the superconducting metal-air (MA) interface changes, resulting in a change in the participation ratio.

In actual measurements, as the distance between the electrodes changes, the electrostatic energy stored in the insulating layer at the superconducting metal-air (vacuum) interface changes, and the internal Q value in measurement changes.

In measurement of a superconducting resonator, the internal Q value representing the loss of the superconducting resonator is connected to the outside (waveguide), and thus the measurer cannot directly obtain the internal Q value.

On the other hand, with respect to the response of the resonator in which a high frequency transmission characteristic S21 and a high frequency reflection characteristic S11 are measured, the amplitudes and phases of the high frequency transmission characteristic S21 and the high frequency reflection characteristic S11 change depending on how strongly the waveguide and the resonator are coupled. An external Q value is defined as an index representing the strength of coupling between the waveguide and the resonator.

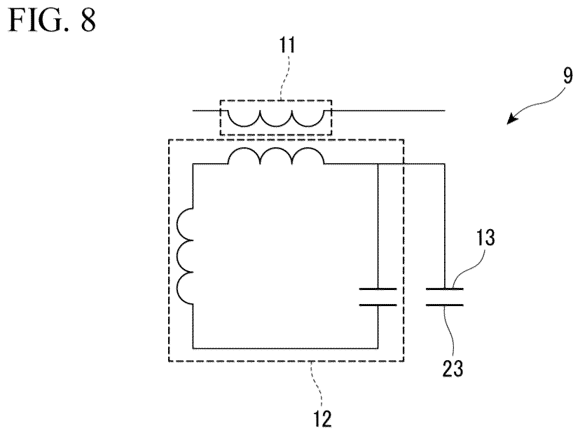

On the other hand, the superconducting resonant circuit 9 of the present embodiment functions as an LC resonant circuit as shown in FIG. 8.

Therefore, the readout waveguide 11 and the lumped constant inductor 12 are connected to the outside of the superconducting resonant circuit 9 through mutual inductance.

Therefore, the measurer can measure the high frequency response characteristics of the superconducting resonant circuit 9 from outside the superconducting resonant circuit 9 by inputting/outputting high frequency waves to/from the readout waveguide 11.

As a result, the measurer can calculate the internal Q value of the superconducting resonant circuit 9 by measuring the high frequency response characteristics (for example, high frequency transmission characteristic S21) of the superconducting resonant circuit 9 from outside the superconducting resonant circuit 9 and fitting the measured high frequency response characteristics.

Measurement of the internal Q value between different superconducting resonant circuits 9 may be performed as many times as possible to accurately extract the statistical properties of the internal Q (median value and variance of the internal Q value) in measurement.

Additionally, a loss amount may be extracted using the internal Q value between different superconducting resonant circuits 9 and the participation ratio calculated from electromagnetic field simulations.

According to an example of the superconducting resonant circuit 9 of the present embodiment, the superconducting resonant circuit 9 moves the second superconducting circuit chip 2 with respect to the first superconducting circuit chip 1 in the facing direction Df to change the inter-electrode distance AA.

As a result, the moving distance of the second superconducting circuit chip 2 corresponds to a change in the inter-electrode distance AA.

Therefore, the measurer can easily set a desired inter-electrode distance AA.

According to an example of the superconducting resonant circuit 9 of the present embodiment, the operating mechanism 3 includes a piezo actuator.

Therefore, the measurer can easily set the inter-electrode distance AA in small increments.

According to an example of the superconducting resonant circuit 9 of the present embodiment, the readout waveguide 11 and the lumped constant inductor 12 are coupled.

Accordingly, the measurer can measure the high frequency response characteristics of the superconducting resonant circuit 9 through the readout waveguide 11.

Therefore, the measurer can easily measure the high frequency response characteristics of the superconducting resonant circuit 9.

In an example of the present embodiment, the readout waveguide 11 is a coplanar waveguide.

Therefore, the measurer can easily measure the high frequency response characteristics of the superconducting resonant circuit 9 with respect to microwaves.

### First Modified Example

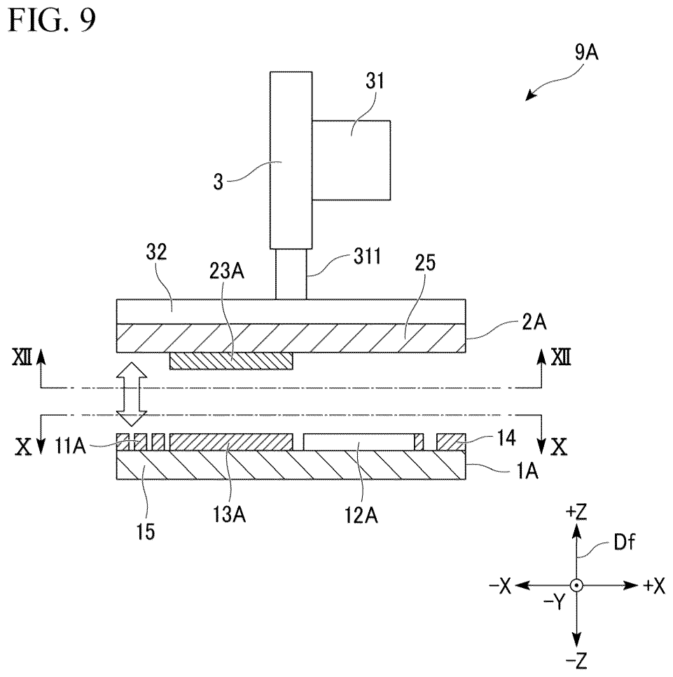

The above-described superconducting resonant circuit 9 may be configured as a superconducting resonant circuit 9A shown in FIG. 9 to FIG. 14 as a first modified example.

The superconducting resonant circuit 9A has the same configuration as the superconducting resonant circuit 9, operates in the same manner, performs the same measurement method, and has the same effects except that the superconducting resonant circuit 9A differs from the superconducting resonant circuit 9 in that the former is coupled to the readout waveguide via a capacitor instead of an inductor.

As shown in FIG. 9, the superconducting resonant circuit 9A includes a first superconducting circuit chip 1A, a second superconducting circuit chip 2A, and an operating mechanism 3.

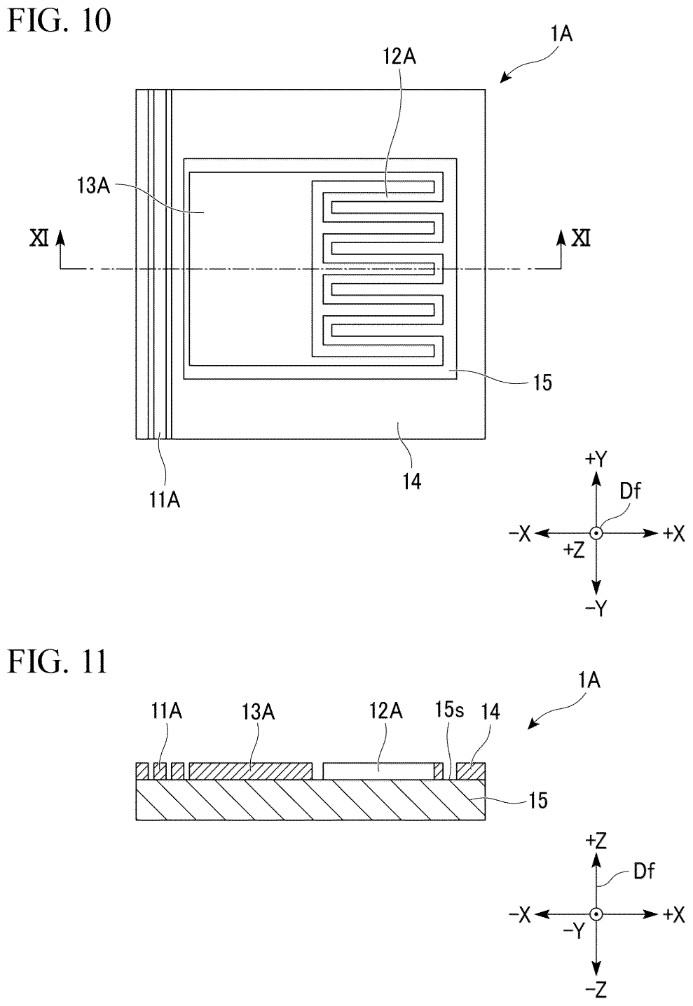

As shown in FIG. 10 and FIG. 11, the first superconducting circuit chip 1A includes a readout waveguide 11A, a lumped constant inductor 12A, a first lumped constant capacitor electrode 13A, a ground pattern 14, and a first substrate 15.

The readout waveguide 11A and the first lumped constant capacitor electrode 13A are coupled to each other with respect to microwaves.

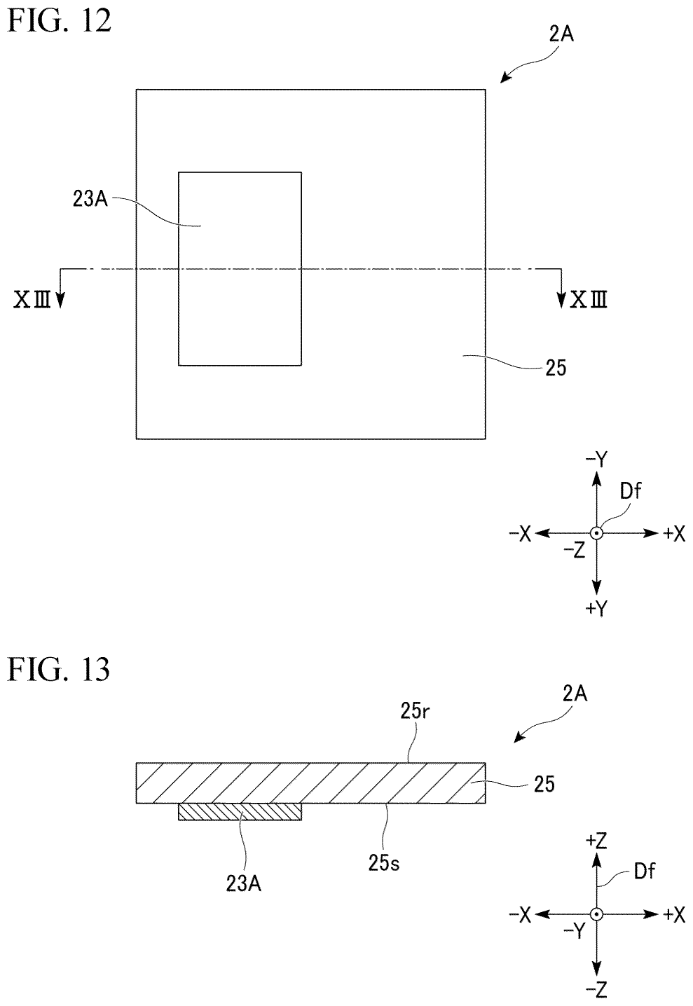

As shown in FIG. 12 and FIG. 13, the second superconducting circuit chip 2A includes a second lumped constant capacitor electrode 23A and a second substrate 25.

The first lumped constant capacitor electrode 13A and the second lumped constant capacitor electrode 23A face each other in the facing direction Df.

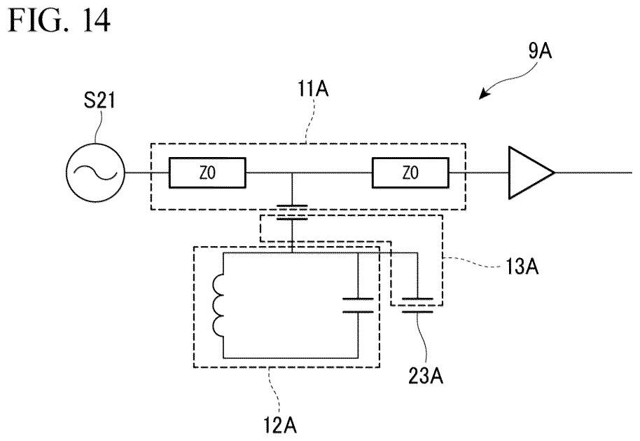

The superconducting resonant circuit 9A of this modified example functions as an LC resonant circuit as shown in FIG. 14.

According to the superconducting resonant circuit 9A of this modified example, the distance between the electrodes can also be changed, and thus the capacitance of the capacitor composed of the first lumped constant capacitor electrode 13A and the second lumped constant capacitor electrode 23A can be changed.

Therefore, the high frequency response characteristics of the superconducting resonant circuit 9A can be measured by changing the capacitance value.

Therefore, according to the superconducting resonant circuit 9A, it takes less time to analyze a dielectric loss.

### Second Modified Example

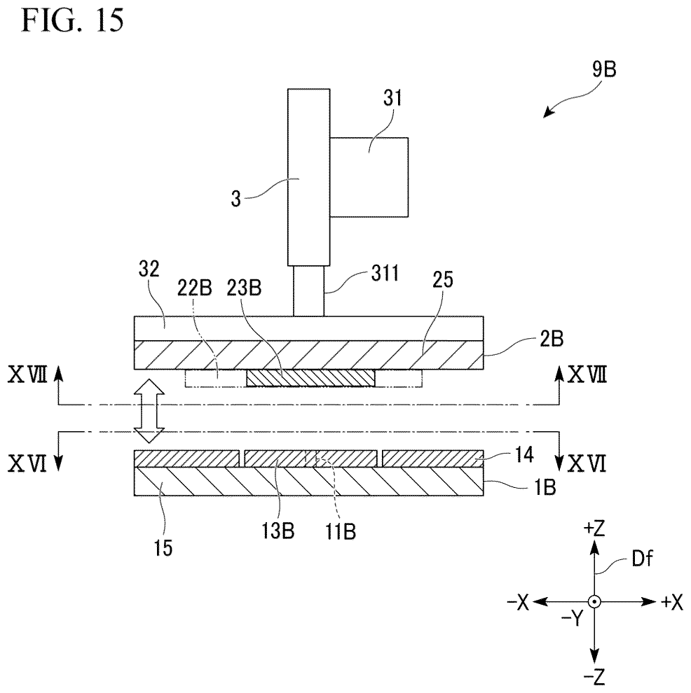

The above-described superconducting resonant circuit 9 may be configured as a superconducting resonant circuit 9B shown in FIG. 15 to FIG. 18 as a second modified example.

The superconducting resonant circuit 9B differs from the superconducting resonant circuit 9 in that the former is a circuit which includes a reflective waveguide, a lumped constant capacitor electrode, and a lumped constant inductor and in which the magnitude of coupling in measurement changes according to change in the distance between the electrodes. Accordingly, the superconducting resonant circuit 9B can extract a loss amount from changes in the external Q value instead of changes in the internal Q value. Other than such points, the superconducting resonant circuit 9B has the same configuration as the superconducting resonant circuit 9, operates in the same manner, performs the same measurement method, and has the same effects.

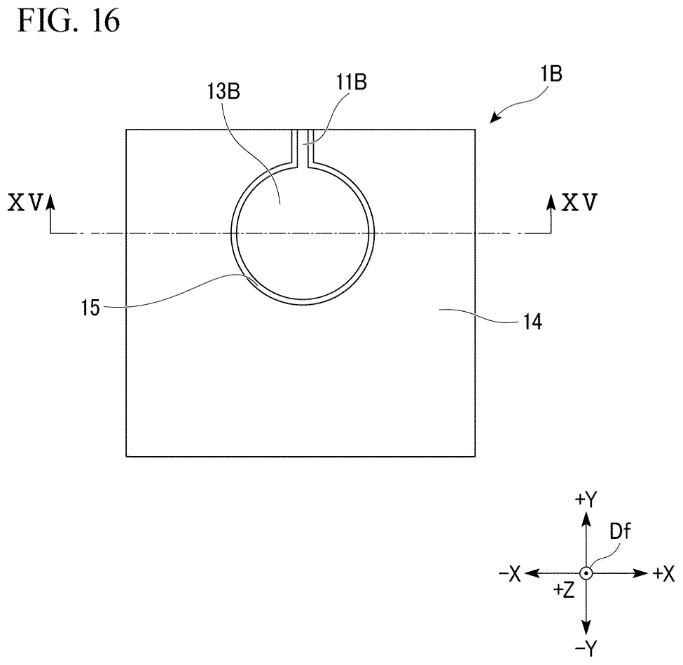

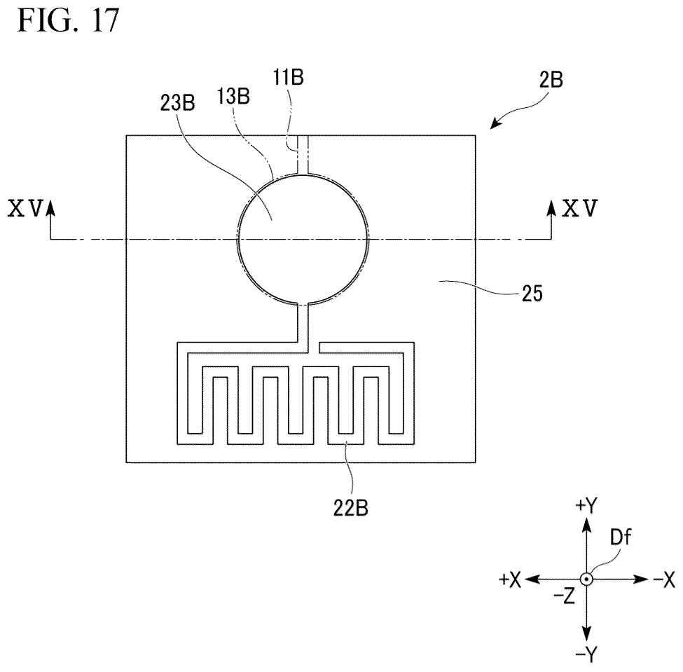

As shown in FIG. 15, the superconducting resonant circuit 9B includes a first superconducting circuit chip 1B, a second superconducting circuit chip 2B, and an operating mechanism 3. Here, the first superconducting circuit chip 1B in FIG. 15 shows a cross section taken along line XV-XV in FIG. 16. Further, the second superconducting circuit chip 2B in FIG. 15 shows a cross section taken along line XV-XV in FIG. 17.

As shown in FIG. 16, the first superconducting circuit chip 1B includes a readout waveguide 11B, a first lumped constant capacitor electrode 13B, a ground pattern 14, and a first substrate 15.

The readout waveguide 11B and the first lumped constant capacitor electrode 13B are a continuous pattern. Accordingly, the readout waveguide 11B and the first lumped constant capacitor electrode 13B are coupled to each other with respect to microwaves.

For example, the readout waveguide 11B may be a coplanar waveguide as shown in FIG. 16.

As shown in FIG. 17, the second superconducting circuit chip 2B includes a lumped constant inductor 22B, a second lumped constant capacitor electrode 23B, and a second substrate 25.

The first lumped constant capacitor electrode 13B and the second lumped constant capacitor electrode 23B face each other in the facing direction Df.

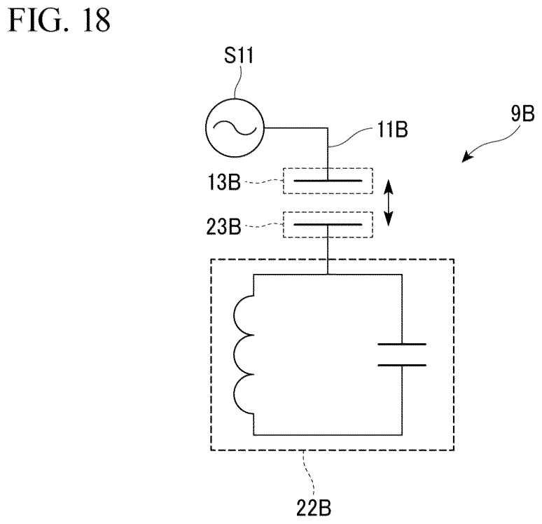

The superconducting resonant circuit 9B of this modified example functions as an LC resonant circuit as shown in FIG. 18.

According to the superconducting resonant circuit 9B of this modified example, the distance between the electrodes can also be changed, and thus the capacitance of the capacitor composed of the first lumped constant capacitor electrode 13B and the second lumped constant capacitor electrode 23B can be changed.

Accordingly, the high frequency response characteristics of the superconducting resonant circuit 9B can be measured by changing the capacitance value.

Therefore, according to the superconducting resonant circuit 9B, it takes less time to analyze a dielectric loss.

### Third Modified Example

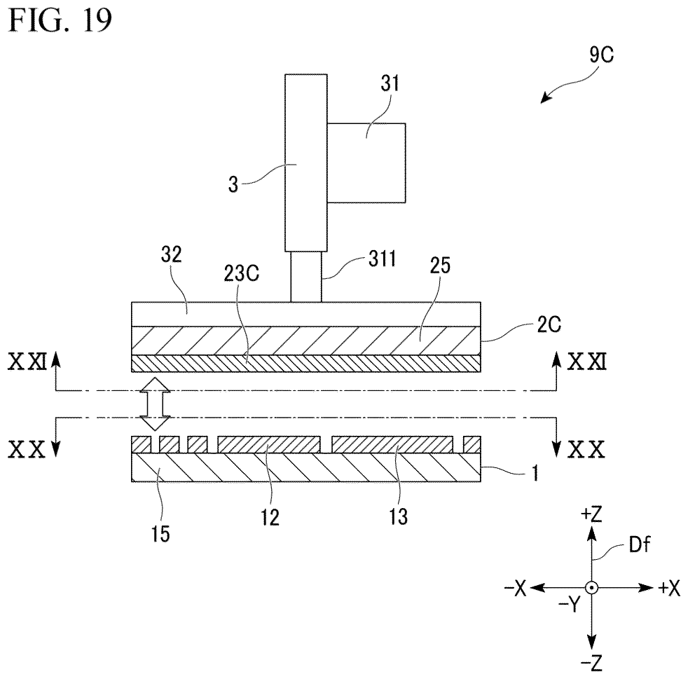

The above-described superconducting resonant circuit 9 may be configured as a superconducting resonant circuit 9C shown in FIG. 19 to FIG. 22 as a third modified example.

The superconducting resonant circuit 9C differs from the superconducting resonant circuit 9 in that the former is a type of circuit in which one lumped constant capacitor electrode is grounded. Other than this difference, the superconducting resonant circuit 9C has the same configuration as the superconducting resonant circuit 9, operates in the same manner, performs the same measurement method, and has the same effects.

As shown in FIG. 19, the superconducting resonant circuit 9C includes a first superconducting circuit chip 1, a second superconducting circuit chip 2C, and an operating mechanism 3.

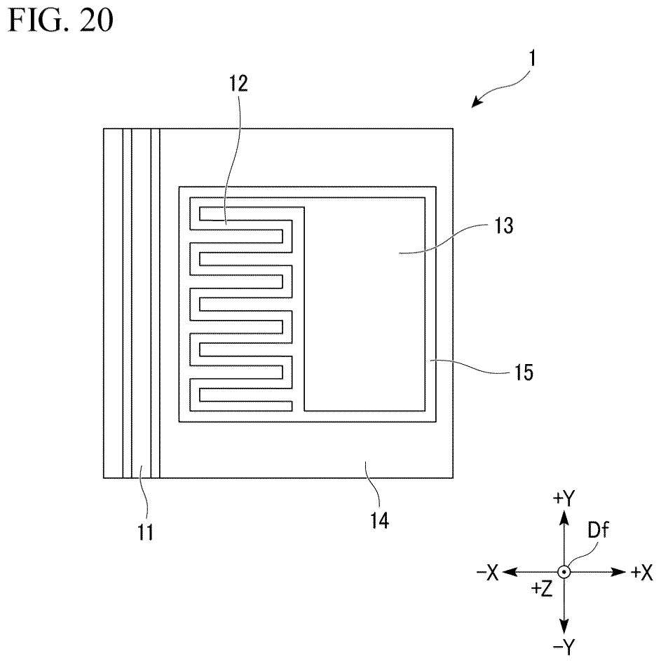

As shown in FIG. 20, like the first superconducting circuit chip 1 shown in FIG. 2 and FIG. 3, the first superconducting circuit chip 1 includes a readout waveguide 11, a lumped constant inductor 12, a first lumped constant capacitor electrode 13, a ground pattern 14, and a first substrate 15.

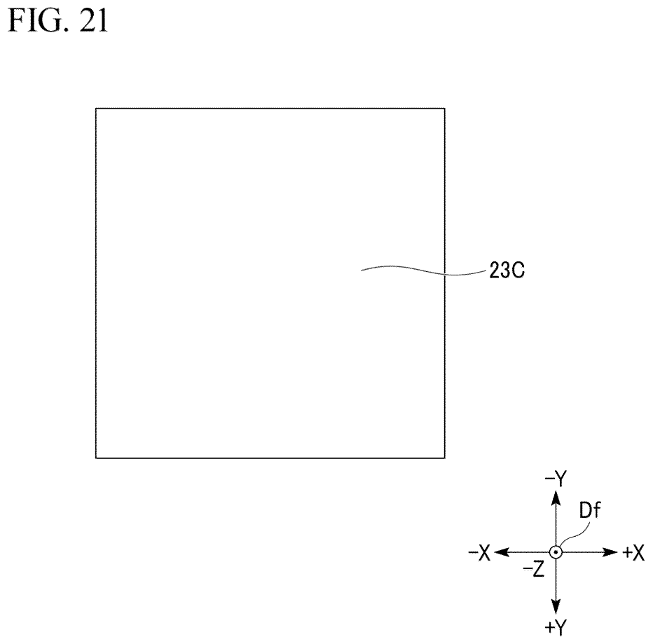

As shown in FIG. 19 and FIG. 21, the second superconducting circuit chip 2C includes a second lumped constant capacitor electrode 23C and a second substrate 25.

The first lumped constant capacitor electrode 13 and the second lumped constant capacitor electrode 23C face each other in the facing direction Df.

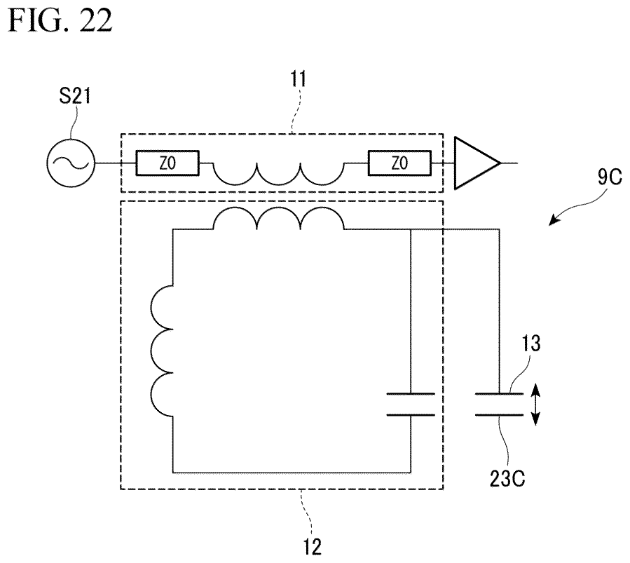

The superconducting resonant circuit 9C of this modified example functions as an LC resonant circuit as shown in FIG. 22.

According to the superconducting resonant circuit 9C of this modified example, the distance between the electrodes can also be changed, and thus the capacitance of the capacitor composed of the first lumped constant capacitor electrode 13 and the second lumped constant capacitor electrode 23C can be changed.

Accordingly, the high frequency response characteristics of the superconducting resonant circuit 9C can be measured by changing the capacitance value.

Therefore, according to the superconducting resonant circuit 9C, it takes less time to analyze a dielectric loss.

### Fourth Modified Example

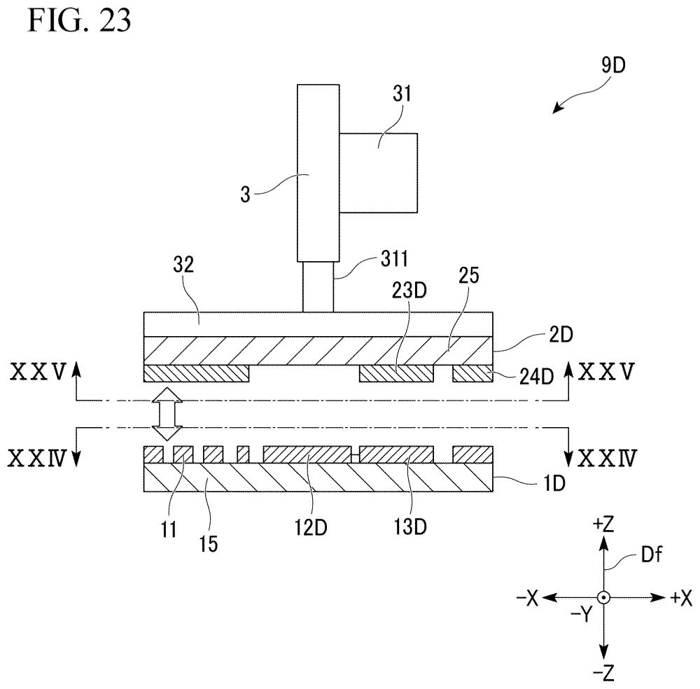

The above-described superconducting resonant circuit 9 may be configured as a superconducting resonant circuit 9D shown in FIG. 23 to FIG. 27 as a fourth modified example.

The superconducting resonant circuit 9D differs from the superconducting resonant circuit 9 in that the former includes two different electrodes having the same potential, as one side electrodes constituting capacitors, and two electrodes each of which is arranged to form a pair with a related electrode of the two different electrodes, as the other side electrodes constituting the capacitor. With this configuration, by increasing the distance between the electrodes (d in FIG. 27, which will be described later), the capacitor formed between both electrodes becomes dominant, and thus it is possible to consider only the contribution of electrostatic energy stored between the superconducting metal and air (vacuum). Other than these differences, the superconducting resonant circuit 9D has the same configuration as the superconducting resonant circuit 9, operates in the same manner, performs the same measurement method, and has the same effects.

As shown in FIG. 23, the superconducting resonant circuit 9D includes a first superconducting circuit chip 1D, a second superconducting circuit chip 2D, and an operating mechanism 3.

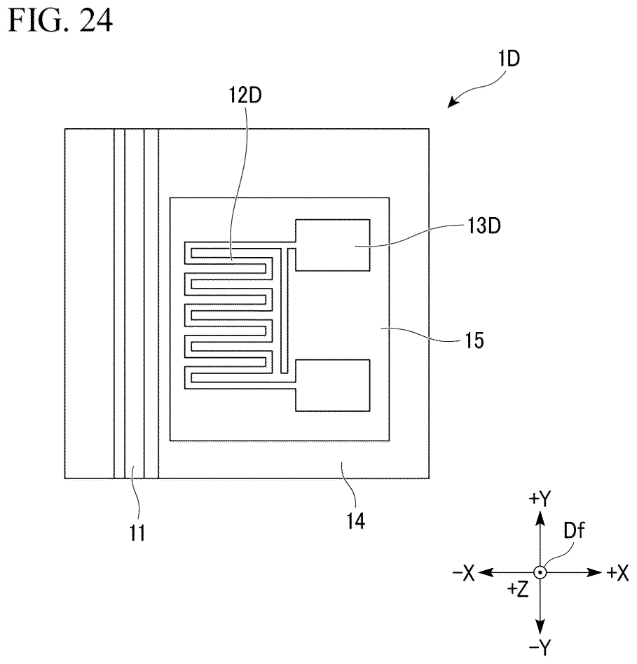

As shown in FIG. 24, the first superconducting circuit chip 1D includes a readout waveguide 11, a lumped constant inductor 12D, two first lumped constant capacitor electrodes 13D, a ground pattern 14 as a first ground pattern, and a first substrate 15.

One of the two first lumped constant type capacitor electrodes 13D is continuously connected to one of both ends of the pattern of the lumped constant inductor 12D.

The other of the two first lumped constant capacitor electrodes 13D is continuously connected to the other of both ends of the pattern of the lumped constant inductor 12D.

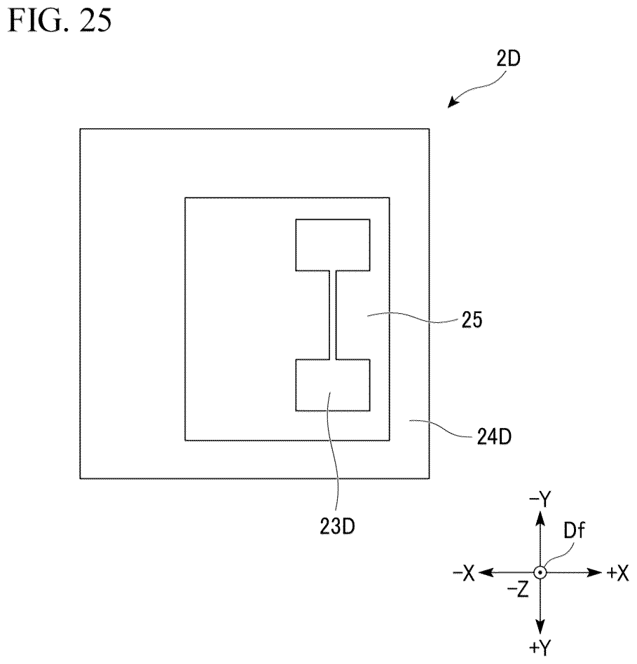

As shown in FIG. 25, the second superconducting circuit chip 2D includes two second lumped constant capacitor electrodes 23D, a second ground pattern 24D, and a second substrate 25.

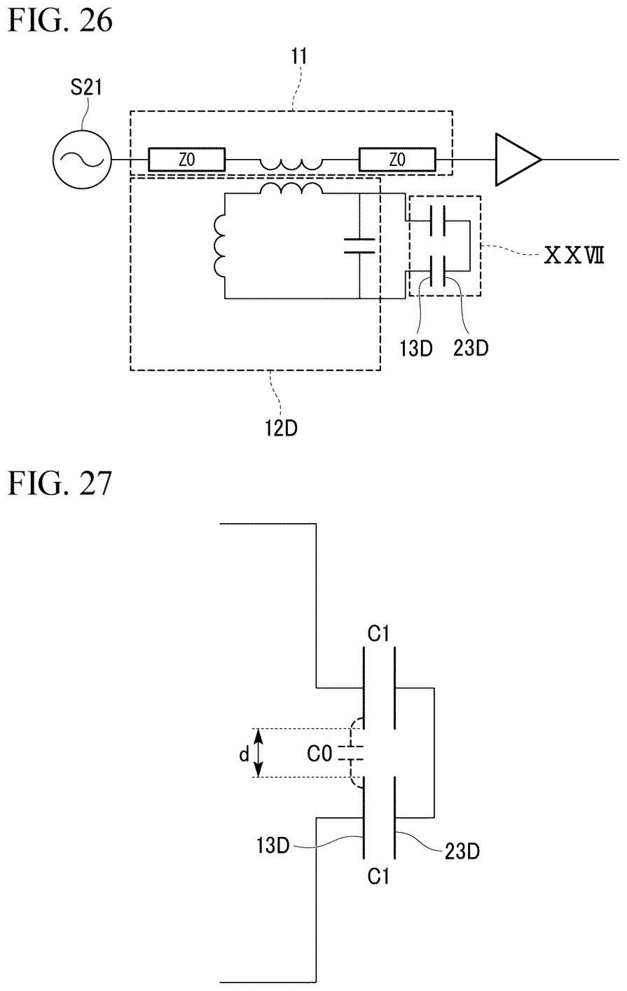

Each first lumped constant capacitor electrode 13D faces the related second lumped constant capacitor electrode 23D on a one-to-one basis in the facing direction Df. The superconducting resonant circuit 9D of this modified example functions as an LC resonant circuit as shown in FIG. 26 and FIG. 27.

According to the superconducting resonant circuit 9D of this modified example, the distance between the electrodes can also be changed, and thus the capacitance of the capacitor composed of the first lumped constant capacitor electrode 13D and the second lumped constant capacitor electrode 23D can be changed.

Accordingly, the high frequency response characteristics of the superconducting resonant circuit 9D can be measured by changing the capacitance value.

Therefore, according to the superconducting resonant circuit 9D, it takes less time to analyze a dielectric loss.

### Other Modified Examples

Although the operating mechanism moves the second superconducting circuit chip with respect to the first superconducting circuit chip in one example of the present embodiment and each modified example, the operating mechanism may be configured in any manner as long as it can move one of the first superconducting circuit chip and the second superconducting circuit chip with respect to the other.

As a modified example, the operating mechanism may change the distance between the electrodes by moving the first superconducting circuit chip with respect to the second superconducting circuit chip.

Although the readout waveguide is a coplanar waveguide in one example of the present embodiment and each modified example, the readout waveguide may be configured in any manner as long as it can transmit read out microwaves.

As a modified example, the readout waveguide may be a microstrip line, a strip line, or a coaxial line.

Although the measurer measures the high frequency transmission characteristic as the high frequency response characteristics of the superconducting resonant circuit in one example of the present embodiment and each modified example, the measurer may measure any high frequency response characteristic as long as they can measure the high frequency response characteristic of the superconducting resonant circuit.

As a modified example, the measurer may measure a high frequency reflection characteristic as the high frequency response characteristics of the superconducting resonant circuit.

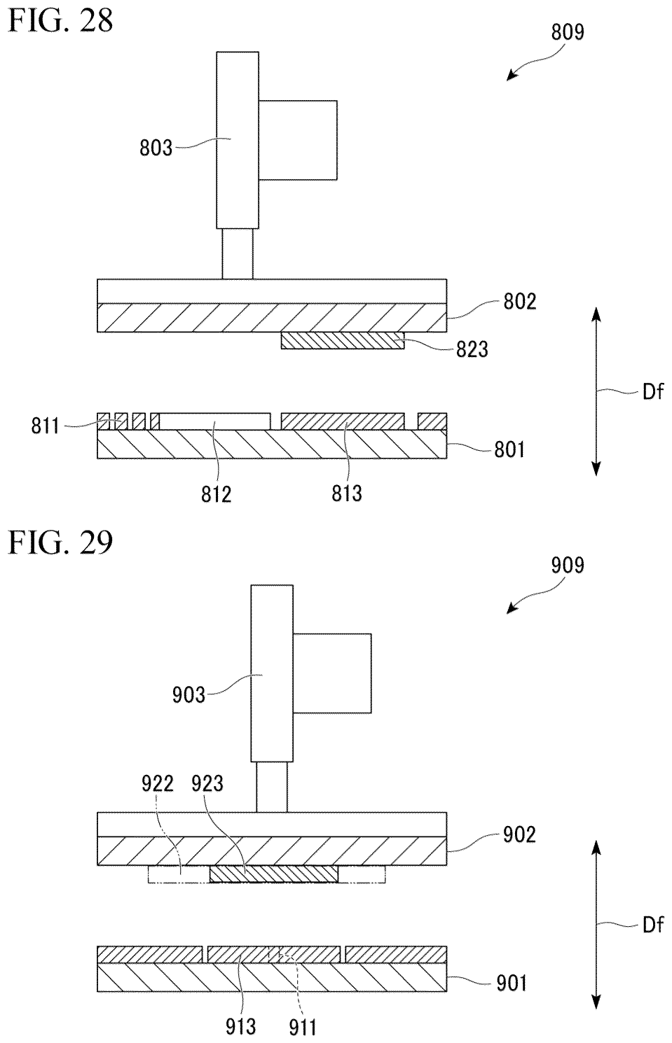

Hereinafter, a superconducting resonant circuit according to some example embodiments of the present disclosure will be described using FIG. 28.

### (Configuration)

The superconducting resonant circuit 809 includes a first superconducting circuit chip 801, a second superconducting circuit chip 802, and an operating mechanism 803.

The first superconducting circuit chip 801 includes a readout waveguide 811, a lumped constant inductor 812, and a first lumped constant capacitor electrode 813.

The second superconducting circuit chip 802 includes a second lumped constant capacitor electrode 823.

The second lumped constant capacitor electrode 823 faces the first lumped constant capacitor electrode 813.

The operating mechanism 803 is capable of changing the inter-electrode distance between the first lumped constant capacitor electrode 813 and the second lumped constant capacitor electrode 823.

### (Operation and Effect)

According to the superconducting resonant circuit 809 of the present embodiment, since the distance between the electrodes can be changed, the capacitance of the capacitor composed of the first lumped constant capacitor electrode 813 and the second lumped constant capacitor electrode 823 can be changed.

Accordingly, the high frequency response characteristics of the superconducting resonant circuit 809 can be measured by changing the capacitance value.

Therefore, according to the superconducting resonant circuit 809, it takes less time to analyze a dielectric loss.

Hereinafter, a superconducting resonant circuit according to some example embodiments of the present disclosure will be described using FIG. 29.

### (Configuration)

The superconducting resonant circuit 909 includes a first superconducting circuit chip 901, a second superconducting circuit chip 902, and an operating mechanism 903.

The first superconducting circuit chip 901 includes a readout waveguide 911 and a first lumped constant capacitor electrode 913.

The second superconducting circuit chip 902 includes a lumped constant inductor 922 and a second lumped constant capacitor electrode 923.

The second lumped constant capacitor electrode 923 faces the first lumped constant capacitor electrode 913.

The operating mechanism 903 can change the inter-electrode distance between the first lumped constant capacitor electrode 913 and the second lumped constant capacitor electrode 923.

### (Operation and Effect)

According to the superconducting resonant circuit 909 of the present embodiment, since the distance between the electrodes can be changed, the capacitance of the capacitor composed of the first lumped constant capacitor electrode 913 and the second lumped constant capacitor electrode 923 can be changed.

Accordingly, the high frequency response characteristics of the superconducting resonant circuit 909 can be measured by changing the capacitance value.

Therefore, according to the superconducting resonant circuit 909, it takes less time to analyze a dielectric loss.

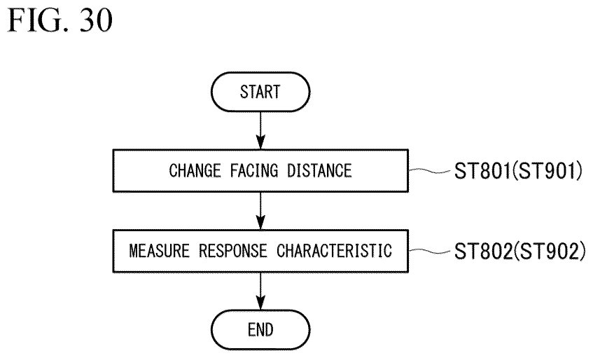

Hereinafter, a measurement method according to some example embodiments of the present disclosure will be described using FIG. 30.

### (Configuration)

The measurement method of the present embodiment includes changing the inter-electrode distance between a first lumped constant capacitor electrode and a second lumped constant capacitor electrode of a superconducting resonant circuit including a first superconducting circuit chip including a readout waveguide, a lumped constant inductor, and the first lumped constant capacitor electrode, and a second superconducting circuit chip including the second lumped constant capacitor electrode facing the first lumped constant capacitor electrode (ST801), and measuring high frequency response characteristics of the superconducting resonant circuit (ST802).

### (Operation and Effect)

According to the measurement method of the present embodiment, since the distance between the electrodes can be changed, the capacitance of the capacitor composed of the first lumped constant capacitor electrode and the second lumped constant capacitor electrode can be changed.

Accordingly, the high frequency response characteristics of the superconducting resonant circuit can be measured by changing the capacitance value.

Therefore, according to the measurement method of the present embodiment, it takes less time to analyze a dielectric loss.

Hereinafter, a measurement method according to some example embodiments of the present disclosure will be described using FIG. 30.

### (Configuration)

The measurement method of the present embodiment includes changing the inter-electrode distance between a first lumped constant capacitor electrode and a second lumped constant capacitor electrode of a superconducting resonant circuit including a first superconducting circuit chip including a readout waveguide and the first lumped constant capacitor electrode, and a second superconducting circuit chip including a lumped constant inductor and the second lumped constant capacitor electrode facing the first lumped constant capacitor electrode (ST901), and measuring high frequency response characteristics of the superconducting resonant circuit (ST902).

### (Operation and Effect)

According to the measurement method of the present embodiment, since the distance between the electrodes can be changed, the capacitance of the capacitor composed of the first lumped constant capacitor electrode and the second lumped constant capacitor electrode can be changed.

Accordingly, the high frequency response characteristics of the superconducting resonant circuit can be measured by changing the capacitance value.

Therefore, according to the measurement method of the present embodiment, it takes less time to analyze a dielectric loss.

Although some example embodiments according to the present disclosure have been described above, these example embodiments are shown as examples and are not intended to limit the scope of the present disclosure. These example embodiments can be implemented in various other forms, and various omissions, substitutions, and changes can be made without departing from the gist of the present disclosure. Each embodiment can be combined with other example embodiments as appropriate.

Part or all of the above example embodiments may be described as in the following supplementary notes, but the example embodiments are not limited to the following.

### (Supplementary Note 1)

A superconducting resonant circuit including:
a first superconducting circuit chip including a readout waveguide, a lumped constant inductor, and a first lumped constant capacitor electrode;
a second superconducting circuit chip including a second lumped constant capacitor electrode facing the first lumped constant capacitor electrode; and
an actuator configured to change an inter-electrode distance between the first lumped constant capacitor electrode and the second lumped constant capacitor electrode.

### (Supplementary Note 2)

The superconducting resonant circuit according to supplementary note 1, wherein the actuator is configured to change the inter-electrode distance by moving one of the first superconducting circuit chip and the second superconducting circuit chip with respect to the other of the first superconducting circuit chip and the second superconducting circuit chip in a direction in which the first lumped constant capacitor electrode and the second lumped constant capacitor electrode face each other.

### (Supplementary Note 3)

The superconducting resonant circuit according to supplementary note 1 or 2, wherein the actuator includes a piezo actuator.

### (Supplementary Note 4)

The superconducting resonant circuit according to any one of supplementary notes 1 to 3, wherein the readout waveguide and the lumped constant inductor are coupled.

### (Supplementary Note 5)

The superconducting resonant circuit according to any one of supplementary notes 1 to 4, wherein the readout waveguide and the first lumped constant capacitor electrode are coupled.

### (Supplementary Note 6)

The superconducting resonant circuit according to any one of supplementary notes 1 to 5, wherein the readout waveguide includes a coplanar waveguide.

### (Supplementary Note 7)

A measurement method for a superconducting resonant circuit including a first superconducting circuit chip including a readout waveguide, a lumped constant inductor, and a first lumped constant capacitor electrode, and a second superconducting circuit chip including a second lumped constant capacitor electrode facing the first lumped constant capacitor electrode, the measurement method including:
changing an inter-electrode distance between the first lumped constant capacitor electrode and the second lumped constant capacitor electrode; and
measuring high frequency response characteristics of the superconducting resonant circuit.

### (Supplementary Note 8)

The measurement method according to supplementary note 7, further including:
extracting a loss amount of the superconducting resonant circuit based on the high frequency response characteristics.

### (Supplementary Note 9)

The measurement method according to supplementary note 7 or 8, wherein the changing includes moving one of the first superconducting circuit chip and the second superconducting circuit chip with respect to the other of the first superconducting circuit chip and the second superconducting circuit chip in a direction in which the first lumped constant capacitor electrode and the second lumped constant capacitor electrode face each other.

### (Supplementary Note 10)

The measurement method according to any one of supplementary notes 7 to 9, wherein the readout waveguide and the lumped constant inductor are coupled.

### (Supplementary Note 11)

The measurement method according to any one of supplementary notes 7 to 10, wherein the readout waveguide and the first lumped constant capacitor electrode are coupled.

### (Supplementary Note 12)

The measurement method according to any one of supplementary notes 7 to 11, wherein the readout waveguide includes a coplanar waveguide.

### (Supplementary Note 13)

A superconducting resonant circuit including:
a first superconducting circuit chip including a readout waveguide and a first lumped constant capacitor electrode;
a second superconducting circuit chip including a lumped constant inductor and a second lumped constant capacitor electrode facing the first lumped constant capacitor electrode; and
an actuator configured to change an inter-electrode distance between the first lumped constant capacitor electrode and the second lumped constant capacitor electrode.

### (Supplementary Note 14)

The superconducting resonant circuit according to supplementary note 13, wherein the actuator is configured to change the inter-electrode distance by moving one of the first superconducting circuit chip and the second superconducting circuit chip with respect to the other of the first superconducting circuit chip and the second superconducting circuit chip in a direction in which the first lumped constant capacitor electrode and the second lumped constant capacitor electrode face each other.

### (Supplementary Note 15)

The superconducting resonant circuit according to supplementary note 13 or 14, wherein the actuator includes a piezo actuator.

### (Supplementary Note 16)

The superconducting resonant circuit according to any one of supplementary notes 13 to 15, wherein the readout waveguide and the first lumped constant capacitor electrode are coupled.

### (Supplementary Note 17)

The superconducting resonant circuit according to any one of supplementary notes 13 to 16, wherein the readout waveguide includes a coplanar waveguide.

### (Supplementary Note 18)

A measurement method for a superconducting resonant circuit including a first superconducting circuit chip including a readout waveguide and a first lumped constant capacitor electrode, and a second superconducting circuit chip including a lumped constant inductor and a second lumped constant capacitor electrode facing the first lumped constant capacitor electrode, the measurement method including:
changing an inter-electrode distance between the first lumped constant capacitor electrode and the second lumped constant capacitor electrode; and
measuring high frequency response characteristics of the superconducting resonant circuit.

### (Supplementary Note 19)

The measurement method according to supplementary note 18, further including:
extracting a loss amount of the superconducting resonant circuit based on the high frequency response characteristics.

### (Supplementary Note 20)

The measurement method according to supplementary note 18 or 19, wherein the changing includes moving one of the first superconducting circuit chip and the second superconducting circuit chip with respect to the other the first superconducting circuit chip and the second superconducting circuit chip in a direction in which the first lumped constant capacitor electrode and the second lumped constant capacitor electrode face each other.

### (Supplementary Note 21)

The measurement method according to any one of supplementary notes 18 to 20, wherein the readout waveguide and the first lumped constant capacitor electrode are coupled.

### (Supplementary Note 22)

The measurement method according to any one of supplementary notes 18 to 20, wherein the readout waveguide includes a coplanar waveguide.

According to the superconducting resonant circuit and the measurement method of the present disclosure, it takes less time to analyze a dielectric loss.

What is claimed is:

1. A superconducting resonant circuit comprising:
a first superconducting circuit chip including a readout waveguide, a lumped constant inductor, and a first lumped constant capacitor electrode;
a second superconducting circuit chip including a second lumped constant capacitor electrode facing the first lumped constant capacitor electrode; and
an actuator configured to change an inter-electrode distance between the first lumped constant capacitor electrode and the second lumped constant capacitor electrode.

2. The superconducting resonant circuit according to claim 1, wherein the actuator is configured to change the inter-electrode distance by moving one of the first superconducting circuit chip and the second superconducting circuit chip with respect to the other of the first superconducting circuit chip and the second superconducting circuit chip in a direction in which the first lumped constant capacitor electrode and the second lumped constant capacitor electrode face each other.

3. The superconducting resonant circuit according to claim 1, wherein the actuator includes a piezo actuator.

4. The superconducting resonant circuit according to claim 1, wherein the readout waveguide and the lumped constant inductor are coupled.

5. The superconducting resonant circuit according to claim 1, wherein the readout waveguide and the first lumped constant capacitor electrode are coupled.

6. The superconducting resonant circuit according to claim 1, wherein the readout waveguide includes a coplanar waveguide.

7. A measurement method for a superconducting resonant circuit including a first superconducting circuit chip including a readout waveguide, a lumped constant inductor, and a first lumped constant capacitor electrode, and a second superconducting circuit chip including a second lumped constant capacitor electrode facing the first lumped constant capacitor electrode, the measurement method comprising:
changing an inter-electrode distance between the first lumped constant capacitor electrode and the second lumped constant capacitor electrode; and
measuring high frequency response characteristics of the superconducting resonant circuit.

8. The measurement method according to claim 7, further comprising:
extracting a loss amount of the superconducting resonant circuit based on the high frequency response characteristics.

9. The measurement method according to claim 7, wherein the changing includes moving one of the first superconducting circuit chip and the second superconducting circuit chip with respect to the other of the first superconducting circuit chip and the second superconducting circuit chip in a direction in which the first lumped constant capacitor electrode and the second lumped constant capacitor electrode face each other.

10. The measurement method according to claim 7, wherein the readout waveguide and the lumped constant inductor are coupled.

11. The measurement method according to claim 7, wherein the readout waveguide and the first lumped constant capacitor electrode are coupled.

12. The measurement method according to claim 7, wherein the readout waveguide includes a coplanar waveguide.

13. A superconducting resonant circuit comprising:
a first superconducting circuit chip including a readout waveguide and a first lumped constant capacitor electrode;
a second superconducting circuit chip including a lumped constant inductor and a second lumped constant capacitor electrode facing the first lumped constant capacitor electrode; and
an actuator configured to change an inter-electrode distance between the first lumped constant capacitor electrode and the second lumped constant capacitor electrode.

14. The superconducting resonant circuit according to claim 13, wherein the actuator is configured to change the inter-electrode distance by moving one of the first superconducting circuit chip and the second superconducting circuit chip with respect to the other of the first superconducting circuit chip and the second superconducting circuit chip in a direction in which the first lumped constant capacitor electrode and the second lumped constant capacitor electrode face each other.

15. The superconducting resonant circuit according to claim 13, wherein the actuator includes a piezo actuator.

16. The superconducting resonant circuit according to claim 13, wherein the readout waveguide and the first lumped constant capacitor electrode are coupled.

17. The superconducting resonant circuit according to claim 13, wherein the readout waveguide includes a coplanar waveguide.
